(19) United States
(12) Patent Application Publication
(10) Pub. No.: US 2026/0288022 A1
(43) Pub. Date: Sep. 24, 2026

(54) LITHOGRAPHY APPARATUS AND METHOD FOR OPERATING THE SAME

(71) Applicant: TAIWAN SEMICONDUCTOR MANUFACTURING COMPANY, LTD., Hsinchu (TW)

(72) Inventors: Ming-Hsin CHEN, Taichung City (TW); Chi YANG, Tainan City (TW); Chan-Kang KUO, Tainan City (TW); Yi-Ming DAI, Hsinchu City (TW)

(73) Assignee: TAIWAN SEMICONDUCTOR MANUFACTURING COMPANY, LTD., Hsinchu (TW)

(21) Appl. No.: 19/084,896

(22) Filed: Mar. 20, 2025

(51) Int. Cl. G03F 7/00; G03F 1/22

(52) U.S. Cl. CPC G03F 7/70983; G03F 1/22; G03F 7/70033; G03F 7/702; G03F 7/70233; G03F 7/70933

(57) ABSTRACT

A method includes following steps. A substrate is loaded onto a substrate stage. An extreme ultraviolet (EUV) light source is activated to pattern a photoresist layer on the substrate. Light emitted by the EUV light source is directed onto a photomask covered with a pellicle. The pellicle includes a pellicle membrane vertically overlapping with a patterned region of the photomask, and pellicle frame disposed between the pellicle membrane and a non-patterned region of the photomask. The pellicle frame includes a frame bar and a vent hole extending through an inner surface and an outer surface of the frame bar, wherein at least a portion of an inner surface of the vent hole extends in a direction non-parallel with a bottom surface of the photomask.

### BACKGROUND

Extreme ultraviolet (EUV) lithography is an optical lithography technique in which the scanner uses light in the extreme ultraviolet region (e.g., spanning wavelengths of approximately one to one hundred nanometers). A light source is configured to emit EUV radiation. For instance, the light source may vaporize a molten metal such as tin into a highly ionized plasma that emits the EUV radiation. The EUV radiation is subsequently guided, using a series of optics (e.g., including multilayer mirrors), into the scanner. In the scanner, the EUV radiation is used to project a pattern, which is etched into a photomask, onto a silicon wafer. The EUV process can be used to fabricate a high resolution pattern of lines onto the silicon wafer, potentially at a scale of seven nanometers or beyond.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a simplified schematic diagram of an example lithography system, according to embodiments of the present disclosure.

FIG. 2 is a cross-sectional view of an example pellicle-photomask structure, in accordance with some embodiments of the present disclosure.

FIG. 3A illustrates an example zoomed-in top view of a pellicle membrane, in accordance with some embodiments of the present disclosure.

FIG. 3B illustrates a cross-sectional view of an example carbon nanotube of the network of carbon nanotubes illustrated in FIG. 3A.

FIGS. 4A-4C are side views of various pellicle frame bars, in accordance with some embodiments of the present disclosure.

FIG. 5 is a zoomed-in view of an example pellicle-photomask structure, in accordance with some embodiments of the present disclosure.

FIG. 6 is a cross-sectional view of an example pellicle-photomask structure, in accordance with some embodiments of the present disclosure.

FIGS. 7A-7C are plan views of various particle trapping recesses, in accordance with some embodiments of the present disclosure.

FIG. 8 is a cross-sectional view of an example pellicle-photomask structure, in accordance with some embodiments of the present disclosure.

FIGS. 9A-9C are plan views of various adhesive coatings, in accordance with some embodiments of the present disclosure.

FIG. 10 is a cross-sectional view of an example pellicle-photomask structure, in accordance with some embodiments of the present disclosure.

FIG. 11 is a zoomed-in view of an example pellicle-photomask structure as shown in FIG. 10, in accordance with some embodiments of the present disclosure.

FIG. 12 is a cross-sectional view of an example pellicle-photomask structure, in accordance with some embodiments of the present disclosure.

FIG. 13 is a zoomed-in view of an example pellicle-photomask structure as shown in FIG. 12, in accordance with some embodiments of the present disclosure.

FIG. 14 is a cross-sectional view of an example pellicle-photomask structure, in accordance with some embodiments of the present disclosure.

FIG. 15 is a zoomed-in view of an example pellicle-photomask structure as shown in FIG. 10, in accordance with some embodiments of the present disclosure.

FIG. 16 is a cross-sectional view of an example pellicle-photomask structure, in accordance with some embodiments of the present disclosure.

FIG. 17 is a flow chart illustrating a lithography process, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated. One skilled in the art will realize, however, that the values or ranges recited throughout the description are merely examples, and may be reduced or varied with the down-scaling of the integrated circuits.

The advanced lithography process, method, and materials described in the current disclosure can be used in many applications, including fin-type field effect transistors (FinFETs) or gate-all-around (GAA) transistors. For example, the fins may be patterned to produce a relatively close spacing between features, for which the above disclosure is well suited. In addition, spacers used in forming fins of FinFETs can be processed according to the above disclosure.

In some embodiments, the present disclosure provides a pellicle for extreme ultraviolet (EUV) lithography systems. As discussed above, an EUV lithography system may use EUV radiation to project a pattern formed in a photomask onto a silicon wafer, and the pattern may be etched into the wafer. In some examples, a pellicle (e.g., a thin, transparent film or membrane) may be used to protect the photomask from contamination. For instance, particles may fall onto the surface of the photomask. When the scanner subsequently prints the photomask pattern onto the wafer, the particles may also print onto the wafer, resulting in defects in the pattern. However, a properly positioned pellicle can prevent the particles from falling onto the photomask.

Despite the pellicle membrane's effectiveness in reducing photomask contamination, contamination can still occur through vent holes in the pellicle frame. Vent holes are integral to pellicle membranes used in EUV lithography systems because these systems often operate under vacuum conditions and transition between vacuum and atmospheric states. The vent holes serve to balance the pressure difference between the pellicle membrane and the photomask, thereby preventing damage to the membrane caused by pressure fluctuations. However, these vent holes can become pathways through which particles pass, potentially landing on the photomask and introducing defects into the printed pattern.

To mitigate this issue, the present disclosure provides, in various embodiments, an improved pellicle frame having vent holes with a non-horizontal inner surface. This non-horizontal inner surface directs particles that pass through the vent holes toward non-patterned regions of the photomask or onto the pellicle membrane, which resides outside the EUV radiation's focal plane. By guiding particles to these areas, the likelihood of contaminants falling on the patterned regions of the photomask is significantly reduced. Consequently, the improved pellicle frame can reduce the occurrence of defects in the printed patterns, enhancing the yield and reliability of the EUV lithography system.

Additional features can be added to the pellicle disclosed herein. Some of the features described below can also be replaced or eliminated for different embodiments. Although some embodiments disclosed below discuss operations that are performed in a particular order, these operations may be performed in other orders as well without departing from the scope of the present disclosure.

Moreover, the pellicle and methods disclosed herein may be deployed in a plurality of applications, including the fabrication of fin-type field effect transistors (finFETs), gate-all-around (GAA) field effect transistors (GAA-FETs), and/or nanosheet-FET. For instance, embodiments of the present disclosure may be well suited for patterning the fins of a finFET, a GAA-FET or a nanosheet-FET to produce a relatively close spacing between features. In further embodiments, spacers used in double-patterning or multi-patterning processes for forming the fins may be processed by using the EUV technique according to embodiments of the present disclosure.

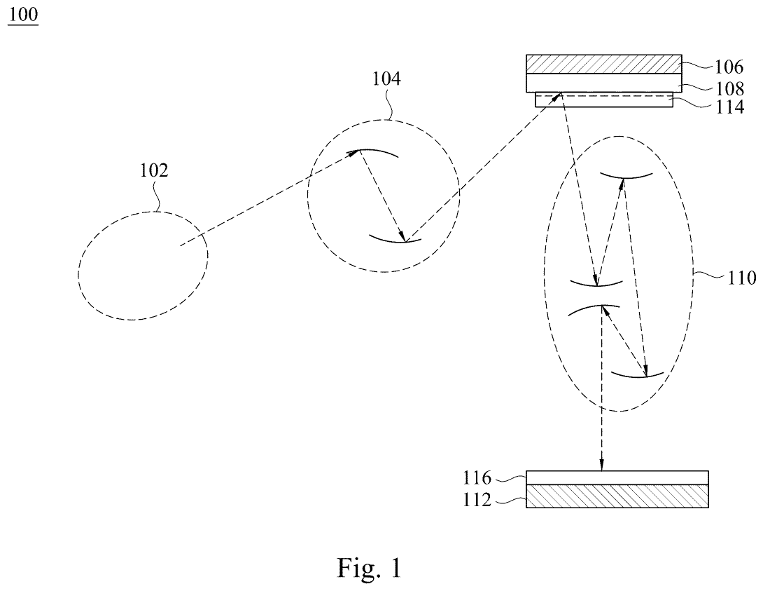

FIG. 1 is a simplified schematic diagram of an example lithography system 100, according to embodiments of the present disclosure. The lithography system 100 may also be referred to herein as a “scanner” that is operable to perform lithography exposing processes with respective radiation sources and exposure modes.

In some embodiments, the lithography system 100 generally comprises a high-brightness light source 102, an illuminator 104, a mask stage 106, a photomask 108, a projection optics module 110, and a substrate stage 112. In some embodiments, the lithography system may include additional components that are not illustrated in FIG. 1. In further embodiments, one or more of the high-brightness light source 102, the illuminator 104, the mask stage 106, the photomask 108, the projection optics module 110, and the substrate stage 112 may be omitted from the lithography system 100 or may be integrated into combined components.

The high-brightness light source 102 may be configured to emit radiation having wavelengths in the range of approximately one nanometer to 250 nanometers. In some embodiments, the high-brightness light source 102 generates EUV light with a wavelength centered at approximately 13.5 nanometers; accordingly, in some embodiments, the high-brightness light source 102 may also be referred to as an “EUV light source.” However, it will be appreciated that the high-brightness light source 102 should not be limited to emitting EUV light. For instance, the high-brightness light source 102 may be utilized to perform any high-intensity photon emission from excited target material.

In some embodiments (e.g., where the lithography system 100 is a UV lithography system), the illuminator 104 comprises various refractive optical components (also referred to as optics), such as a single lens or a lens system comprising multiple lenses (zone plates). In other embodiments (e.g., where the lithography system 100 is an EUV lithography system or EUV tool), the illuminator 104 comprises various reflective optical components, such as a single mirror or a mirror system comprising multiple mirrors. The illuminator 104 may direct light from the high-brightness light source 102 onto the mask stage 106, and more particularly onto the photomask 108 that is secured onto the mask stage 106. In an embodiment where the high-brightness light source 102 generates light in the EUV wavelength range, the illuminator 102 comprises reflective optics.

The mask stage 106 may be configured to secure the photomask 108. In some embodiments, the mask stage 106 may include an electrostatic chuck (e-chuck) to secure the photomask 108. This is because the gas molecules absorb EUV light, and the lithography system 100 for EUV lithography patterning is maintained in a vacuum environment to minimize EUV intensity loss. Herein, the terms “photomask,” “mask,” and “reticle” may be used interchangeably. In one embodiment, the photomask 108 is a reflective mask.

In some embodiments, a pellicle 114 may be positioned over the photomask 108, e.g., between the photomask 108 and the substrate stage 112. The pellicle 114 may protect the photomask 108 from particles and may keep the particles out of focus, so that the particles do not produce an image (which may cause defects on a wafer during the lithography process).

The projection optics module 110 may be configured for imaging the pattern of the photomask 108 onto a semiconductor wafer 116 secured on the substrate stage 112. In one embodiment, the projection optics module 110 comprises refractive optics (such as for a UV lithography system). In another embodiment, the projection optics module 110 comprises reflective optics (such as for an EUV lithography system). The light directed from the photomask 108, carrying the image of the pattern defined on the photomask 108, may be collected by the projection optics module 110. The illuminator 104 and the projection optics module 110 may be collectively referred to as an “optical module” of the lithography system 100.

In some embodiments, the semiconductor wafer 116 may be a bulk semiconductor wafer. For instance, the semiconductor wafer 116 may comprise a silicon wafer. The semiconductor wafer 116 may include silicon or another elementary semiconductor material, such as germanium. In some embodiments, the semiconductor wafer 116 may include a compound semiconductor. The compound semiconductor may include gallium arsenide, silicon carbide, indium arsenide, indium phosphide, another suitable material, or a combination thereof.

In some embodiments, the semiconductor wafer 116 includes a silicon-on-insulator (SOI) substrate. The SOI substrate may be fabricated using a separation by implantation of oxygen (SIMOX) process, a wafer bonding process, another applicable process, or a combination thereof.

In some embodiments, the semiconductor wafer 116 comprises an undoped substrate. However, in other embodiments, the semiconductor substrate 116 comprises a doped substrate, such as a p-type substrate or an n-type substrate.

In some embodiments, the semiconductor wafer 116 includes various doped regions (not shown) depending on the design requirements of the semiconductor device structure. The doped regions may include, for embodiment, p-type wells and/or n-type wells. In some embodiments, the doped regions are doped with p-type dopants. For embodiment, the doped regions may be doped with boron or boron fluoride. In other embodiments, the doped regions are doped with n-type dopants. For embodiment, the doped regions may be doped with phosphor or arsenic. In some embodiments, some of the doped regions are p-doped and other doped regions are n-doped.

In some embodiments, an interconnection structure may be formed over the semiconductor wafer 116. The interconnection structure may include multiple interlayer dielectric layers, including dielectric layers. The interconnection structure may also include multiple conductive features formed in the interlayer dielectric layers. The conductive features may include conductive lines, conductive vias, and/or conductive contacts.

In some embodiments, various device elements are formed in the semiconductor wafer 116. Embodiments of the various device elements may include transistors (e.g., metal oxide semiconductor field effect transistors (MOSFETs), complementary metal oxide semiconductor (CMOS) transistors, bipolar junction transistors (BJTs), high-voltage transistors, high-frequency transistors, p-channel and/or n-channel field effect transistors (PFETs and/or NFETs), diodes, or other suitable elements. Various processes may be used to form the various device elements, including deposition, etching, implantation, photolithography, annealing, and/or other applicable processes.

The device elements may be interconnected through the interconnection structure over the semiconductor wafer 116 to form integrated circuit devices. The integrated circuit devices may include logic devices, memory devices (e.g., static random access memory (SRAM) devices), radio frequency (RF) devices, input/output (I/O) devices, system-on-chip (SoC) devices, image sensor devices, other applicable devices, or a combination thereof.

In some embodiments, the semiconductor wafer 116 may be coated with a photoresist layer that is sensitive to EUV light. Various components including those described above may be integrated together and may be operable to perform lithography exposing processes.

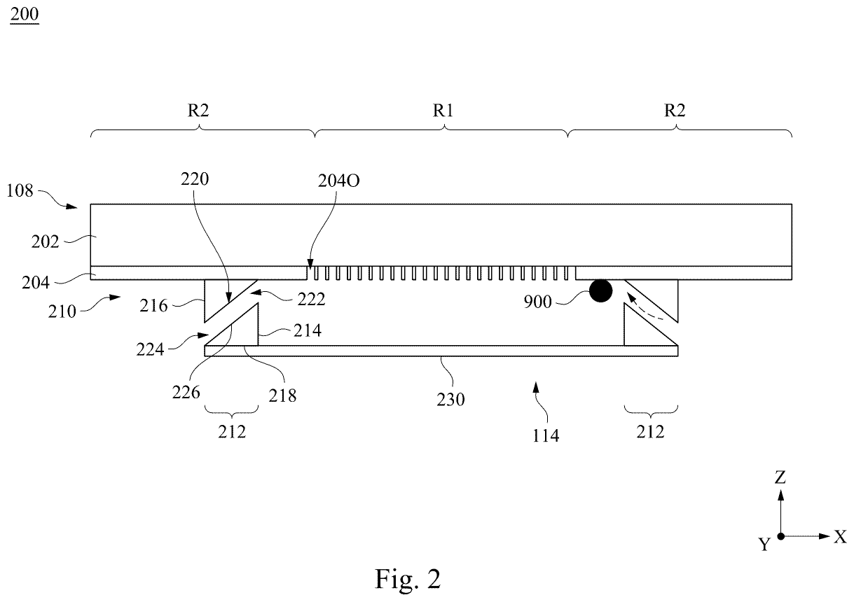

FIG. 2 is a cross-sectional view of an example pellicle-photomask structure 200, in accordance with some embodiments of the present disclosure. As illustrated in FIG. 2, the photomask 108 may include a mask substrate 202 and a mask pattern 204 positioned on a surface of the mask substrate 204.

In some embodiments, the mask substrate 202 comprises a transparent substrate, such as fused silica that is relatively free of defects, borosilicate glass, soda-lime glass, calcium fluoride, low thermal expansion material, ultra-low thermal expansion material, or other applicable materials. The mask pattern 204 may be positioned on the mask substrate 202 and may be designed according to the integrated circuit features to be formed over a semiconductor substrate (e.g., wafer 116 of FIG. 1) during a lithography process. The mask pattern 204 may be formed by depositing a material layer over the mask substrate 202 and patterning the material layer to have one or more patterned openings 204O where beams of radiation may travel through without being absorbed, and one or more absorption areas which may completely or partially block the beams of radiation. As illustrated in FIG. 2, the mask pattern 204 of the photomask 108 includes a patterned region R1 where the one or more patterned openings 204O are located, and a non-patterned region R2 which lacks any patterned opening. The non-patterned region R2 surrounds the patterned region R1.

In some embodiments, the mask pattern 204 may include metal, metal alloy, metal silicide, metal nitride, metal oxide, metal oxynitride, or other applicable materials. Examples of materials that may be used to form the mask pattern 204 may include, but are not limited to, Cr, MoₓSi_{y}, TaₓSi_{y}, Mo, NbₓO_{y}, Ti, Ta, CrₓN_{y}, MoₓO_{y}, MoₓN_{y}, CrₓO_{y}, TiₓN_{y}, ZrₓN_{y}, TiₓO_{y}, TaₓN_{y}, TaₓO_{y}, SiₓO_{y}, NbₓN_{y}, ZrₓN_{y}, AlₓO_{y}N_{z}, TaₓB_{y}O_{z}, TaₓB_{y}N_{z}, AgₓO_{y}, AgₓN_{y}, Ni, NiₓO_{y}, NiₓO_{y}N_{z}, and/or the like. The compound x/y/z ratio is not limited. In some embodiments, the photomask 108 is an EUV mask. However, in some other embodiments, the photomask 108 may be an optical mask.

As illustrated in FIG. 2, the pellicle 114 vertically overlaps with the entire patterned region R1 of the photomask 108. This vertical overlap serves to protect the patterned region R1 from foreign contamination. The pellicle 114 includes a pellicle frame 210 vertically overlapping with the photomask 108, and attached to the bottom surface of the non-patterned region R2 of the photomask 108. In some embodiments, the pellicle frame 210 may be formed from Si, SiC, SiN, glass, a low coefficient of thermal expansion material (such as an Al alloy, a Ti alloy, or the like), another suitable material, or a combination thereof. In some embodiments, suitable processes for forming the pellicle frame 210 may include machining processes, sintering processes, photochemical etching processes, other applicable processes, or a combination thereof.

As illustrated in FIG. 2, the pellicle-photomask structure 200 further includes a pellicle membrane 230 positioned below the pellicle frame 210, and adhered to the pellicle frame 210. The pellicle frame 210 may mechanically support the pellicle membrane 230 around the periphery of the pellicle membrane 230. In some embodiments, the pellicle membrane 230 may be formed from a transparent carbon-based film or a transparent silicon-based film, such as a carbon nanotube film or a silicon nanowire film.

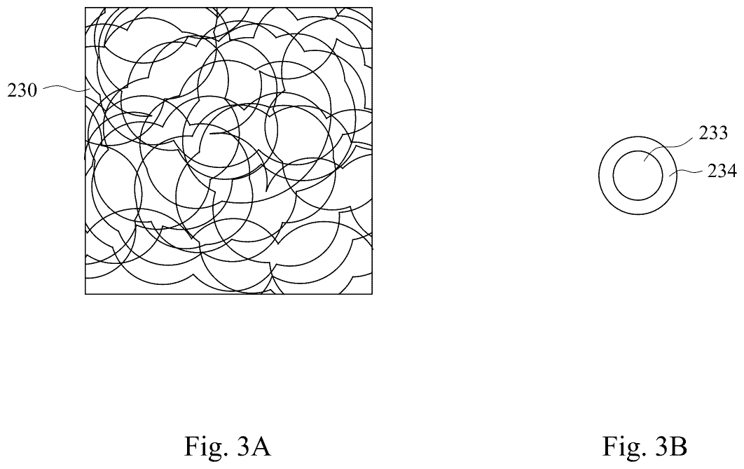

FIG. 3A, for instance, illustrates an example zoomed-in top view of a pellicle membrane 230. In the embodiment illustrated in FIG. 3A, the pellicle membrane 230 comprises a carbon nanotube film. In this embodiment, the network of carbon nanotubes making up the carbon nanotube film may have a structure density of between 0.2 and one, depending on the desired percentage of radiation to be transmitted by the pellicle 114. For instance, carbon nanotube films have been shown to achieve up to approximately ninety percent visible light transmittance. In general, a one nanometer tube thickness for the carbon nanotubes should translate into approximately 0.5 to one percent absorption for radiation in the extreme ultraviolet wavelengths. The precise structure density may be chosen to maximize EUV radiation transmission while minimizing passage of particles through the pellicle membrane. For instance, although a looser structure density may allow for greater EUV radiation transmission, the looser structure density may also allow particles to fall through to the photomask 108. The carbon nanotube film may be formed by a roll-to-roll process, another suitable process, or any combination thereof.

In some embodiments, the carbon-based film or the silicon-based film may further be coated with a protective shell. FIG. 3B, for instance, illustrates a cross-sectional view of an example carbon nanotube 233 of the network of carbon nanotubes illustrated in FIG. 3A. As illustrated, the carbon nanotube 233 is coated with a protective shell 234. The protective shell 234 may comprise, for instance, Ru, Mo, Zr, B, Nb, MoSi, SiN, SiO, another suitable material, or a combination thereof. The protective shell 234 may have a thickness that is between 0.1 and ten nanometers. The material and the thickness of the protective shell 234 may be selected to provide high transmission of EUV radiation, to dissipate heat from the pellicle membrane 230, and to minimize dissipation with the film material (e.g., carbon or silicon). In some embodiments, the protective shell 234 may be deposited onto the network of carbon nanotubes using atomic layer deposition, physical vapor deposition, chemical vapor deposition, wet chemical plating, another suitable process, or any combination thereof.

In some embodiments, the thickness of the pellicle membrane 230 is between ten nanometers and one hundred nanometers, which provides high EUV transmission. In general, the thicker the pellicle membrane 230, the more robust the pellicle membrane 230 will be; however, if the pellicle membrane 230 is too thick, the percentage of EUV transmission may decrease. Thus, the disclosed ranges strike a balance between these two aims.

In some embodiments, as illustrated in FIG. 2, the pellicle frame 210 may include a plurality of frame bars 212 adhered to the non-patterned region R2 of the photomask 108. A frame bar 212 has an inner surface 214 and an outer surface 216, where the inner surface 214 and the outer surface 216 are oriented on opposite sides of the frame bar 212. The pellicle frame 210 may further include a bottom surface 218 that connects the inner surface 214 and the outer surface 216.

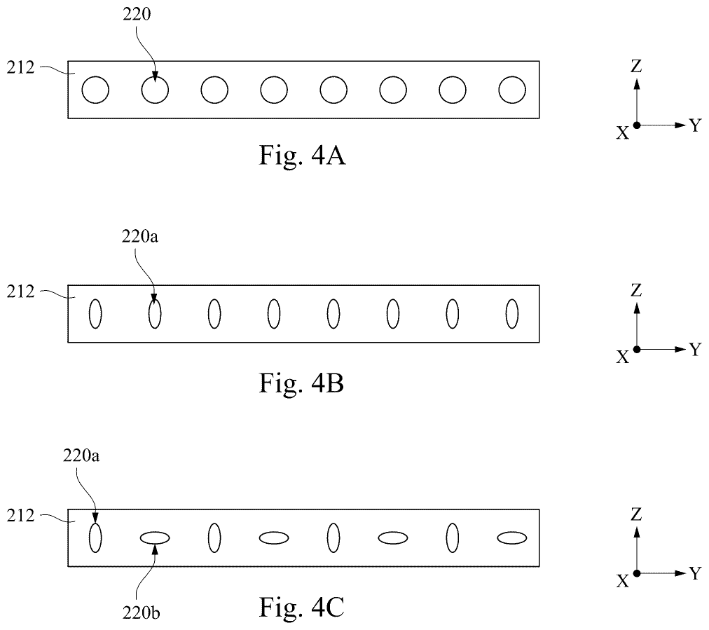

As illustrated in FIG. 2, the frame bar 212 has one or more vent holes 220 extending from the inner surface 214 to the outer surface 216. The one or more vent holes 220 are designed to facilitate pressure equalization across the pellicle membrane 230. The one or more vent holes 220 may have any side-view pattern, including circular side-view pattern, elliptical side-view pattern, rectangular side-view pattern, slit-shaped side-view pattern, other shapes, or any combination thereof. For example, in an embodiment as shown in the side view of FIG. 4A taken along Y-Z plane, the frame bar 212 includes a plurality vent holes 220 each having a circular side-view pattern, and the circular vent holes 220 are arranged along a linear path extending along Y-direction. In an embodiment as shown in the side view of FIG. 4B taken along Y-Z plane, the frame bar 212 includes a plurality vent holes 220a each having an elliptical side-view pattern, and the elliptical vent holes 220a are arranged along a linear path extending along Y-direction. In an embodiment as shown in the side view of FIG. 4C taken along Y-Z plane, the frame bar 212 includes a plurality of vent holes 220a with vertically extended elliptical side-view patterns, and a plurality of vent holes 220b with horizontally extended elliptical side-view patterns. The vertically extended elliptical vent holes 220a are alternating with the horizontally extended elliptical vent holes 220b. The arrangement alternates between the vertically and horizontally extended elliptical vent holes 220a and 220b, providing a strategic pattern for effective venting.

As shown in FIG. 2, the vent hole 220 includes an outer port 224, which is an opening located on the outer surface 216 of the frame bar 212. The outer port 224 serves as the initial point of entry for air or gas that flows into a region between the pellicle membrane 230 and the photomask 108. The design of the outer port 224 can vary depending on the specific pattern of the vent hole, such as circular, elliptical, or slit-shaped. As shown in FIG. 2, the outer port 224 is flush with the outer surface 216 of the frame bar 212 to maintain a smooth profile on the outer surface 216, minimizing any potential disruption to the airflow or accumulation of particulates. The size and shape of the outer port 224 are engineered to optimize the flow characteristics, achieving efficient pressure equalization without compromising the structural integrity of the pellicle frame 210.

As shown in FIG. 2, the vent hole 220 includes an inner port 222, which is an opening located on the inner surface 214 of the frame bar 212, opposite the outer port 224. This inner port 222 allows the air or gas to exit into the internal space confined within the pellicle frame 210 between the pellicle membrane 230 and the photomask 108. Like the outer port 224, design of the inner port 222 is influenced by the overall pattern of the vent hole 220 and is crafted to achieve a seamless transition of airflow. The inner port 222 is also designed to be flush with the inner surface 214 to prevent any obstruction or interference with the pellicle membrane 230. Both the inner and outer ports 222 and 224 are integral to the vent hole's function, working in tandem to facilitate the equalization of pressure across the pellicle membrane 230.

In some embodiments as illustrated in FIG. 2, the inner port 222 and the outer port 224 of the vent hole 220 are located at different elevations, and connected by non-horizontal inner surfaces 226. For example, the inner port 222 is at an elevation higher than the outer port 224, and connected to the outer port 224 by inner surfaces 226 that extend in a direction at an angle relative to the horizontal plane (i.e., X-Y plane as shown in FIG. 2). This vertical offset between the ports 222, 224 of the vent hole 220, and these sloped inner surfaces 226 serve to influence the trajectory of particles (e.g., particle 900) attempting to traverse the vent hole 220, which in turn guides the particles onto the non-patterned region R2, not onto the patterned region R1. By guiding the particles onto the non-patterned region R2, the patterned region R1 can be substantially free of particles. Therefore, the pellicle frame 210 can reduce the occurrence of defects in the printed patterns formed in the wafer 116.

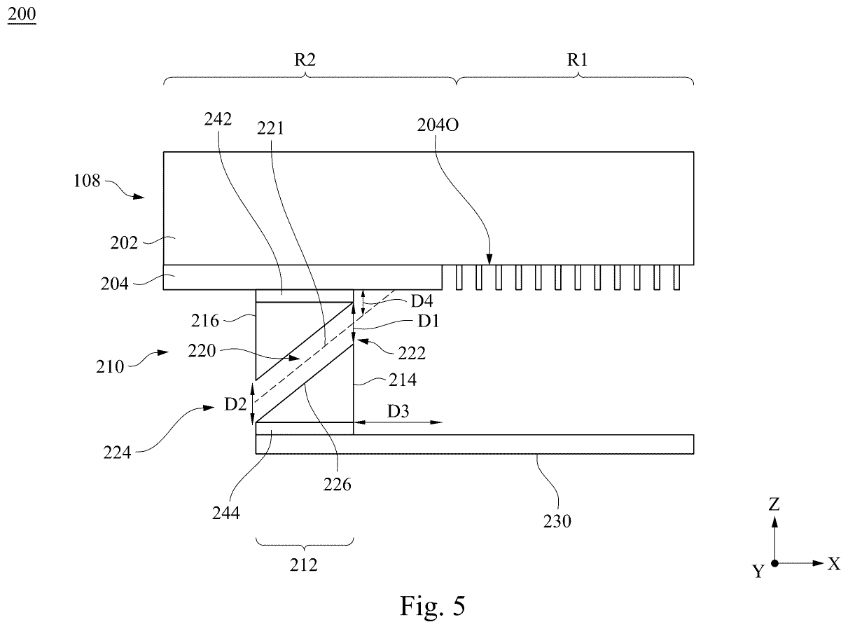

In some embodiments, as illustrated in the zoomed-in view of pellicle-photomask structure 200 shown in FIG. 5, the vent hole 220 has a longitudinal axis 221 extending in a direction parallel with the sloped inner surfaces 226. This longitudinal axis 221 is an imaginary line that extends linearly through the central axis of the vent hole 220, connecting the center point of the outer port 224 with the center point of the inner port 222. The orientation and positioning of the longitudinal axis 221 are such that it extends into the non-patterned region R2 of the photomask 108, not into the patterned region R1 of the photomask 108. This strategic design allows particles passing through the vent hole 220 to fall onto the non-patterned region R2, not onto the patterned region R1, thereby preventing defects caused in the printed patterns formed using the photomask 108.

As shown in FIG. 5, the inner port 222 has a vertical dimension D1, which extends in the Z-direction. This dimension represents the vertical extent of the inner port 222, which may also be referred to as the diameter if the inner port 222 is configured as a circular opening, as illustrated in FIG. 4A. Similarly, the outer port 224 has a vertical dimension D2, also extending in the Z-direction, which likewise may be referred to as the diameter in the case of a circular configuration. In some embodiments, the vertical dimension D1 of the inner port 222 is designed to be substantially equivalent to the vertical dimension D2 of the outer port 224. This equivalence in dimensions promotes uniformity in the cross-sectional profile of the vent hole 220 along its longitudinal axis 221. Such a design consideration may be advantageous for maintaining consistent airflow characteristics through the vent hole 220, thereby improving the pressure equalization across the pellicle-photomask structure 200. In some embodiments, the vertical dimension D1 of the inner port 222 and/or the vertical dimension D2 of the outer port 224 are different from a width of the patterned openings 204O within the mask pattern 204. For example, the vertical dimension D1 of the inner port 222 and/or the vertical dimension D2 of the outer port 224 are greater than a width of the patterned openings 204O within the mask pattern 204.

As depicted in FIG. 5, the inner port 222 of the vent hole 220 is strategically positioned such that it is laterally offset from the boundary between the patterned region R1 and the non-patterned region R2 by a non-zero distance D3. The non-zero distance D3 represents the horizontal displacement of the inner port 222 relative to the boundary between the patterned region R1 and the non-patterned region R2. By disposing the inner port 222 entirely within the non-patterned region R2, this configuration effectively directs any particles or contaminants that may pass through the vent hole 220 to settle onto the non-patterned region R2, which allows for maintaining the integrity and cleanliness of the patterned region R1.

In some embodiments, the pellicle-photomask structure 200 further incorporates a vertical distance D4 from the center of the inner port 222 to the mask pattern 204 that is less than the non-zero lateral distance D3. This vertical distance D4 is carefully calibrated to allow that any particles or contaminants passing through the vent hole 220 are directed onto the non-patterned region R2 before they have the opportunity to reach the patterned region R1. By optimizing both the lateral and vertical positioning of the inner port 222, the pellicle-photomask structure 200 enhances the protective measures for the patterned region R1, minimizing the risk of contamination that could lead to defects in the printed pattern formed in the wafer 116. This dual-dimensional offset, both lateral and vertical, allows that the vent hole 220 functions effectively as a barrier against particulate contamination, directing potential contaminants away from the sensitive patterned region R1.

In certain embodiments, the vent hole 220 is formed by a drilling process, which results in a surface roughness on the sloped inner surfaces 226 of the vent hole 220 that is greater than the surface roughness of the inner surface 214 and outer surface 216 of the frame bar 212. This increased roughness is an outcome of the drilling technique employed, which may inherently leave behind particles or debris within the vent hole 220. Despite the potential for residual particles to remain within the vent hole 220 post-drilling, the pellicle-photomask structure 200 incorporates an unequal elevation between the inner port 222 and the outer port 224, and sloped inner surfaces 226 connecting the inner port 222 and the outer port 224. This elevation difference can serve to guide any dislodged particles towards the non-patterned region R2, not towards the patterned region R1.

In some embodiments, as illustrated in FIG. 5, the pellicle-photomask structure 200 further includes a pellicle frame adhesive 242 positioned between the pellicle frame 210 and the mask pattern 204. In some examples, the pellicle frame adhesive 242 may be formed from a crosslink type adhesive, a thermoplastic elastomer type adhesive, a polystyrene type adhesive, an acrylic type adhesive, a silicon-based adhesive, an epoxy type adhesive, or a combination thereof. In some embodiments, a surface treatment may be performed on the pellicle frame 210 to enhance the adhesion of the frame bar 212 to the pellicle frame adhesive 242. In some examples, the surface treatment may include an oxygen plasma treatment, another applicable treatment, or a combination thereof. However, in other embodiments, no surface treatment may be performed on the pellicle frame 210.

In some embodiments, the pellicle-mask structure 200 may further include a pellicle membrane adhesive 244 positioned between the pellicle frame 210 and the pellicle membrane 230. In some embodiments, the pellicle membrane adhesive 244 may be formed from a thermoplastic elastomer type adhesive, a polystyrene type adhesive, an acrylic type adhesive, a silicon-based adhesive, an epoxy type adhesive, another suitable adhesive, or a combination thereof. In some embodiments, the pellicle membrane adhesive 244 may be formed from a material that is different from the material making up the pellicle frame adhesive 242.

In some embodiments, either or both of the pellicle frame adhesive 242 and the pellicle membrane adhesive 244 may include heat-dissipating fillers. The heat-dissipating fillers may include, for example, aluminum nitride, boron nitride, aluminum oxide, magnesium oxide, silicon oxide, graphite, metal powder, ceramic powder, another suitable material, or a combination thereof. In some embodiments, the EUV lithography process may involve a high-energy light beam that penetrates the pellicle membrane 230, causing the temperature of the pellicle membrane 230 to increase. The heat-dissipating fillers may help to dissipate the heat of the pellicle membrane 230 through the pellicle membrane adhesive 244, to the pellicle frame 210, to the pellicle frame adhesive 242, to the photomask 108 and the EUV lithography apparatus. Thus, the temperature of the pellicle membrane 230 may be decreased during EUV lithography processing, thereby reducing the likelihood of the pellicle membrane 230 rupturing.

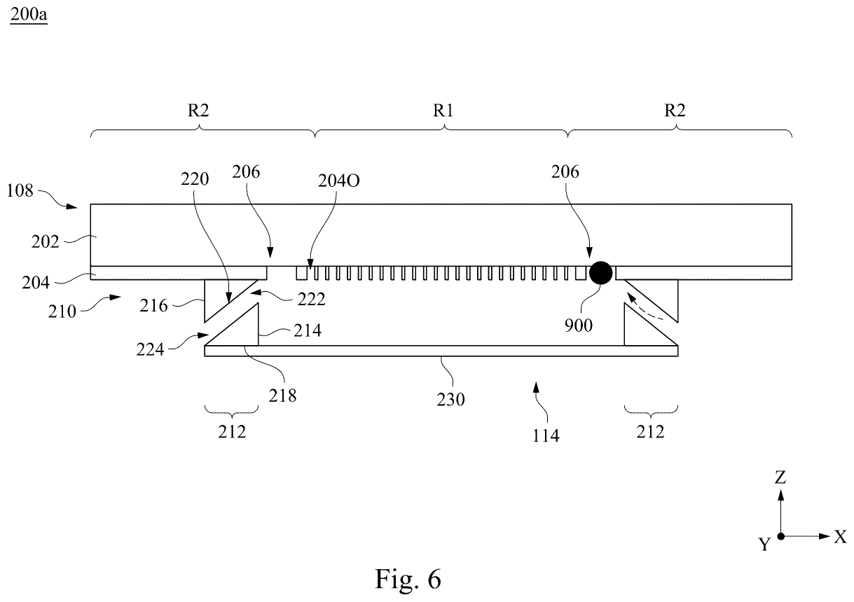

FIG. 6 is a cross-sectional view of an example pellicle-photomask structure 200a, in accordance with some embodiments of the present disclosure. The pellicle-photomask structure 200a is substantially the same as the pellicle-photomask structure 200 discussed previously, except that the pellicle-photomask structure 200a further includes one or more particle trapping recesses 206 formed within the non-patterned regions R2 of the mask pattern 204. The particle trapping recesses 206 are formed with a depth sufficient to capture and retain foreign particles, such as the particle 900. In some embodiments, the particle trapping recesses 206 extend laterally along the periphery of the patterned region R1, creating isolated zones that prevent trapped particles from migrating into the patterned region R1 during the lithography process.

In some embodiments, as illustrated in FIG. 6, the depths of the particle trapping recess 206 are greater than the depth of the openings 204O within the patterned region R1. This is because the particle trapping recesses 206 and the openings 204O serve for different functions. The increased depth of the particle trapping recess 206 is advantageous as it provides a larger volume and surface area for trapping particles, thereby enhancing its capacity to contain and isolate foreign particles. On the other hand, the openings 204O within the patterned region R1 are designed to facilitate the transmission of EUV radiation. These openings 204O are formed to allow EUV radiation to pass through without being absorbed by the mask pattern 204. As a result, the depth of these openings 204O is controlled to meet the requirements of EUV radiation transmission, which may be a shallower depth compared to the particle trapping recesses 206. Due to the deeper depth of the particle trapping recesses 206, the particle trapping recesses 206 may extend into the mask substrate 202.

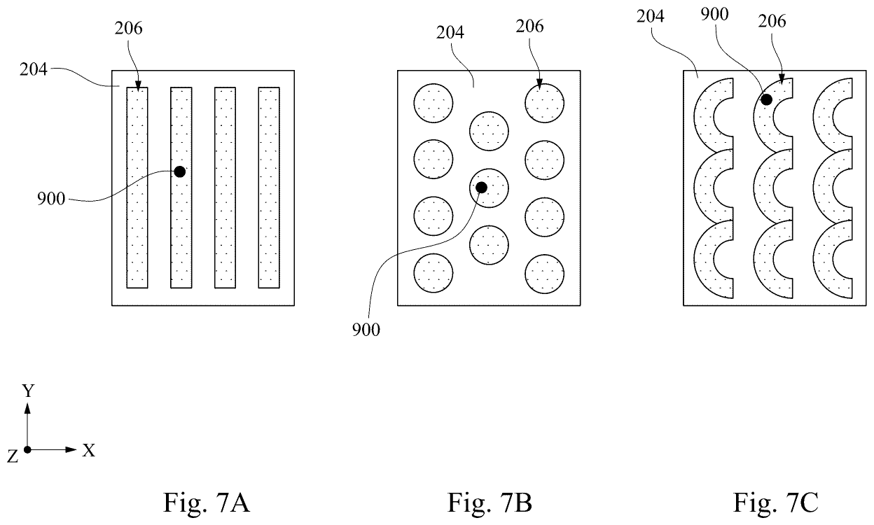

The particle trapping recesses 206 may have any plan-view pattern, including circular plan-view pattern, elongated plan-view pattern, or irregularly shaped plan-view pattern. For example, in an embodiment as shown in a plan view of FIG. 7A taken along X-Y plane, the particle trapping recesses 206 each have an elongated pattern, resembling a rectangular shape. This configuration may be effective for capturing particles along a linear path, maximizing the surface area available for particle retention within a constrained space. In an embodiment as shown in a plan view of FIG. 7B taken along X-Y plane, the particle trapping recesses 206 each have a circular pattern. This configuration is advantageous for uniformly distributing captured particles around the recess 206, potentially reducing localized stress concentrations and enhancing the overall structural integrity of the particle trapping recesses 206. In an embodiment as shown in a plan view of FIG. 7C taken along X-Y plane, the particle trapping recesses 206 are semi-ring patterns arranged in rows and columns, with each column includes a series of contiguous semi-ring patterns. The contiguous nature of the semi-ring patterns within each column allows for a continuous trapping path, which can enhance the likelihood of particle capture as particles traverse the recesses 206. This configuration may provide a balance between maximizing the trapping surface area and maintaining structural support between adjacent recesses 206.

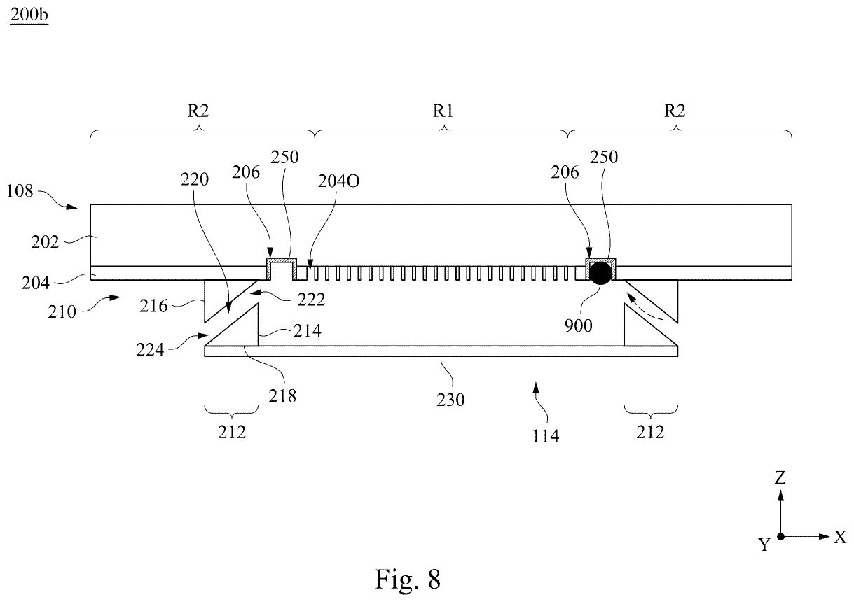

FIG. 8 is a cross-sectional view of an example pellicle-photomask structure 200b, in accordance with some embodiments of the present disclosure. The pellicle-photomask structure 200b is substantially the same as the pellicle-photomask structure 200a discussed previously, except that the pellicle-photomask structure 200b further includes adhesive coatings 250 on surfaces of the particle trapping recesses 206.

The adhesive coating 250 is disposed to enhance the particle retention capabilities of the particle trapping recesses 206. The adhesive coating 250 may include a material selected for its adhesive properties, which can include, but are not limited to, polymer-based adhesives, pressure-sensitive adhesives, or other suitable adhesive compounds. The choice of adhesive material may be influenced by factors such as the operating environment, the types of particles expected to be encountered, and the desired longevity of the adhesive properties.

The application of the adhesive coatings 250 to the surfaces of the particle trapping recesses 206 can be achieved through various deposition techniques, such as spray coating, dip coating, or spin coating, among others. These methods can form a uniform and consistent layer of adhesive material across the surfaces of the particle trapping recesses 206, thereby maximizing the contact area available for particle adhesion. An optional patterning process, such as lithography and etching processes, may be performed to remove materials of the adhesive coatings 250 from regions outside the particle trapping recesses 206. The thickness of the adhesive coating 250 is meticulously controlled to achieve an optimal balance between effective particle capture and maintaining sufficient recess depth for particle retention. This balance ensures that the adhesive coatings 250 are thick enough to capture particles effectively while still allowing the recesses 206 to retain particles without compromising their functional integrity. In some embodiments, the adhesive coatings 250 may be applied with a thickness ranging from a few micrometers to several tens of micrometers, depending on the specific application requirements.

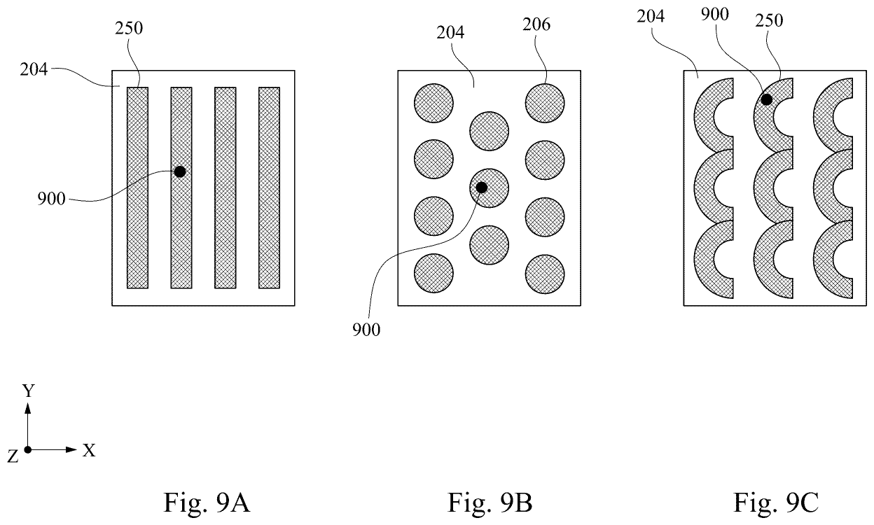

The adhesive coatings 250 may have any plan-view pattern, including circular plan-view pattern, elongated plan-view pattern, or irregularly shaped plan-view pattern. For example, in an embodiment as shown in a plan view of FIG. 9A taken along X-Y plane, the adhesive coatings 250 each have an elongated pattern, resembling a rectangular shape. This configuration may be effective for capturing particles along a linear path, maximizing the surface area available for particle retention within a constrained space. In an embodiment as shown in a plan view of FIG. 9B taken along X-Y plane, the adhesive coatings 250 each have a circular pattern. In an embodiment as shown in a plan view of FIG. 9C taken along X-Y plane, the adhesive coatings 250 are semi-ring patterns arranged in rows and columns, with each column includes a series of contiguous semi-ring patterns. The contiguous nature of the semi-ring patterns within each column allows for a continuous trapping path, which can enhance the likelihood of particle capture as particles traverse the adhesive coatings 250.

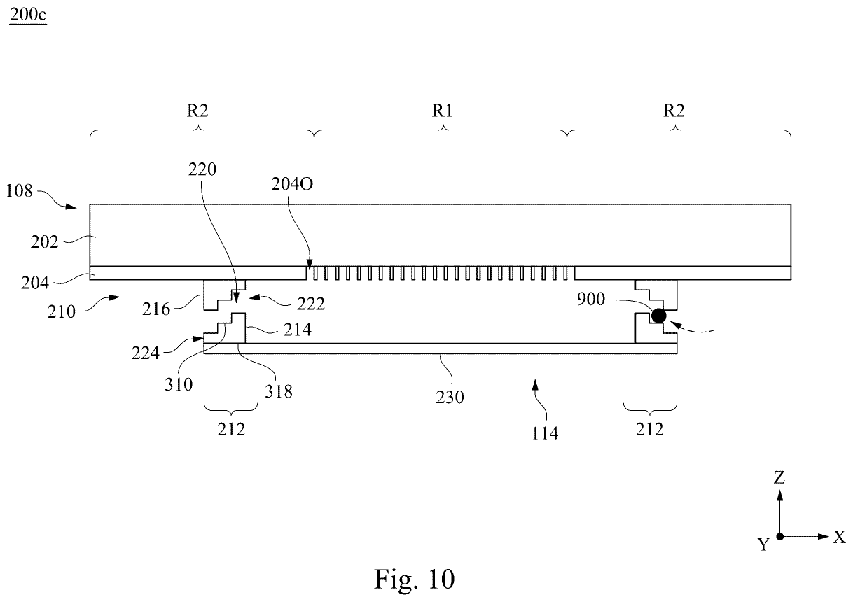

FIG. 10 is a cross-sectional view of an example pellicle-photomask structure 200c, in accordance with some embodiments of the present disclosure. The pellicle-photomask structure 200c is substantially the same as the pellicle-photomask structure 200 discussed previously, except that the vent hole 220 of the pellicle-photomask structure 200c includes a stepped inner surface structure 310 connecting the inner port 222 and the outer port 224.

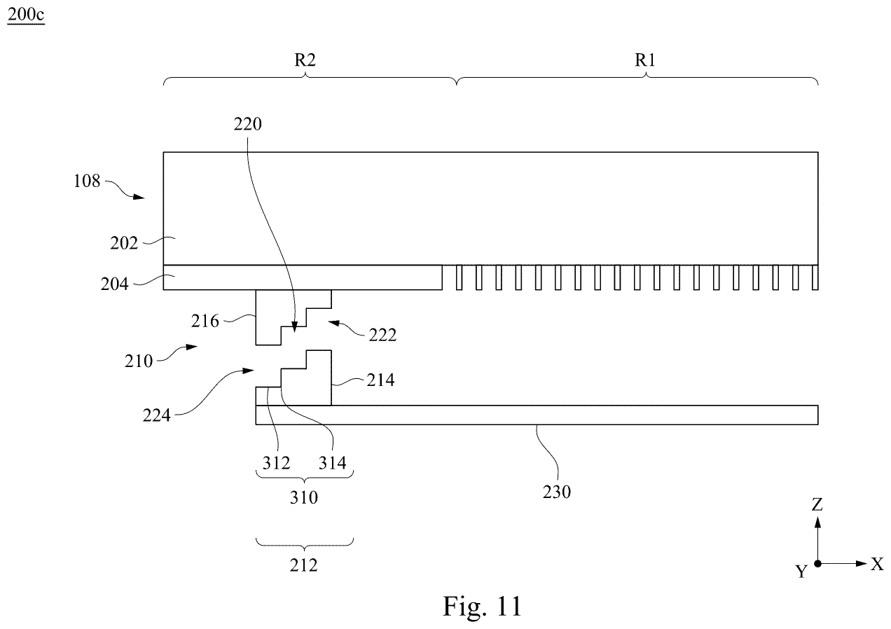

In some embodiments, as illustrated in the zoomed-in view of FIG. 11, the stepped inner surface structure 310 includes a series of alternating horizontal surfaces 312 and non-horizontal surfaces 314, creating a staircase-like profile. The horizontal surfaces 312 are oriented to extend along the X-direction, providing horizontal sections that contribute to the stepped configuration. These horizontal surfaces 312 are parallel to the bottom surface of the mask pattern 204. Interspersed between the horizontal surfaces 312 are the non-horizontal surfaces 314, which may be oriented to extend in the Z-direction, non-parallel with the bottom surface of the mask pattern 204. These non-horizontal surfaces 314 are substantially vertical, forming the risers of the stepped surface structure 310. The alternating arrangement of horizontal and non-horizontal surfaces 312, 314 creates a series of steps that facilitate the transition between different levels within the vent hole 220. The stepped configuration can block the particles (e.g., particle 900 as shown in FIG. 10) from passing through the vent hole 220. Stated another way, the particles may be stuck in the vent hole 220, instead of passing through the vent hole 220, thereby preventing particles or contaminants from falling on the patterned region R1 of the photomask 108.

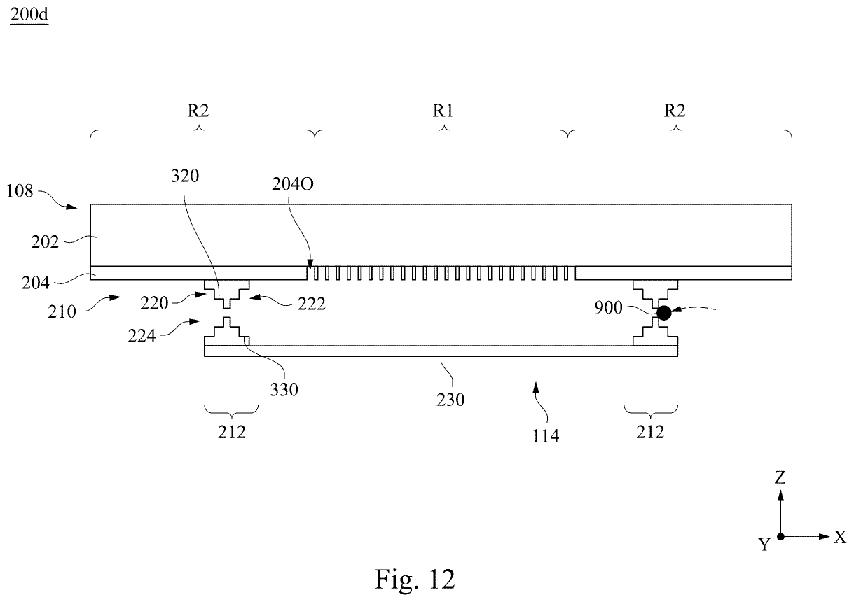

FIG. 12 is a cross-sectional view of an example pellicle-photomask structure 200d, in accordance with some embodiments of the present disclosure. The pellicle-photomask structure 200d is substantially the same as the pellicle-photomask structure 200 discussed previously, except that the vent hole 220 of the pellicle-photomask structure 200c has an upper stepped inner surface structure 320 and a lower stepped inner surface structure 330 substantially symmetrical to the upper stepped inner surface structure 320. The inner port 222 and the outer port 224 are respectively at opposite sides of the stepped inner surface structures 320 and 330.

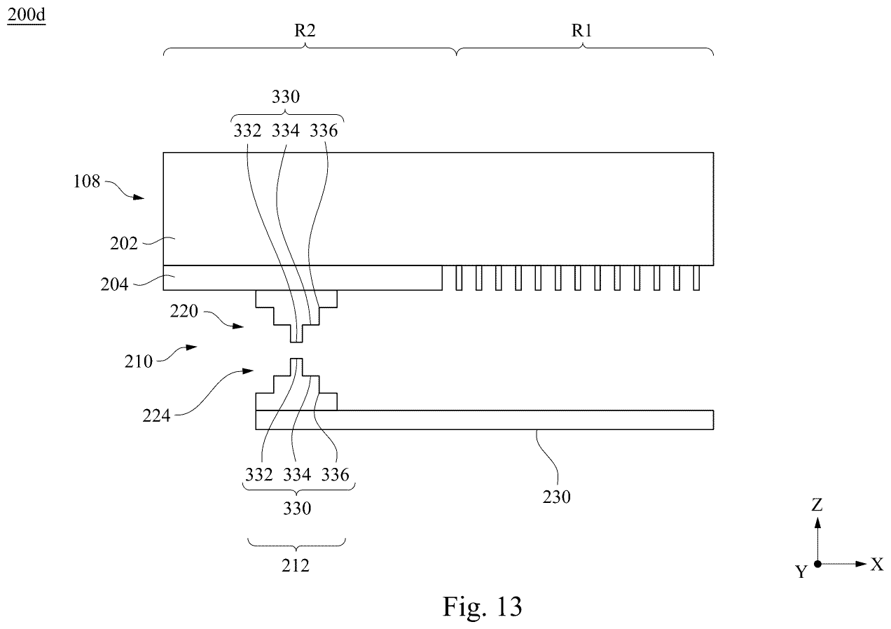

In some embodiments, as illustrated in the zoomed-in view of FIG. 13, the upper stepped inner surface structure 320 includes a central horizontal surface 322 extending along the X-direction. On either side of this central horizontal surface 322, there are symmetrical stepped extensions each including a series of alternating horizontal surfaces 324 and non-horizontal surfaces 326, creating staircase-like profile at opposite sides of the central horizontal surface 322. The horizontal surfaces 324 are oriented to extend along the X-direction, providing horizontal sections that contribute to the stepped configuration. Interspersed between the horizontal surfaces 324 and 322 are the non-horizontal surfaces 326, which may be oriented to extend in the Z-direction, non-parallel with the bottom surface of the mask pattern 204. These non-horizontal surfaces 326 are substantially vertical, forming the risers of the upper stepped inner surface structure 320.

The lower stepped inner surface structure 330 generally mirrors the cross-sectional profile of the upper stepped inner surface structure 320 but in an inverted orientation. Specifically, the upper stepped inner surface structure 320 includes a central horizontal surface 332 extending along the X-direction. On either side of this central horizontal surface 332, there are symmetrical stepped extensions each including a series of alternating horizontal surfaces 334 and non-horizontal surfaces 336, creating staircase-like profile at opposite sides of the central horizontal surface 332. The horizontal surfaces 334 are oriented to extend along the X-direction, providing horizontal sections that contribute to the stepped configuration. Interspersed between the horizontal surfaces 334 and 332 are the non-horizontal surfaces 336, which may be oriented to extend in the Z-direction, non-parallel with the bottom surface of the mask pattern 204. These non-horizontal surfaces 336 are substantially vertical, forming the risers of the upper stepped inner surface structure 330. The stepped configuration can block the particles (e.g., particle 900 as shown in FIG. 12) from passing through the vent hole 220. Stated another way, the particles may be stuck in the vent hole 220, instead of passing through the vent hole 220, thereby preventing particles or contaminants from falling on the patterned region R1 of the photomask 108.

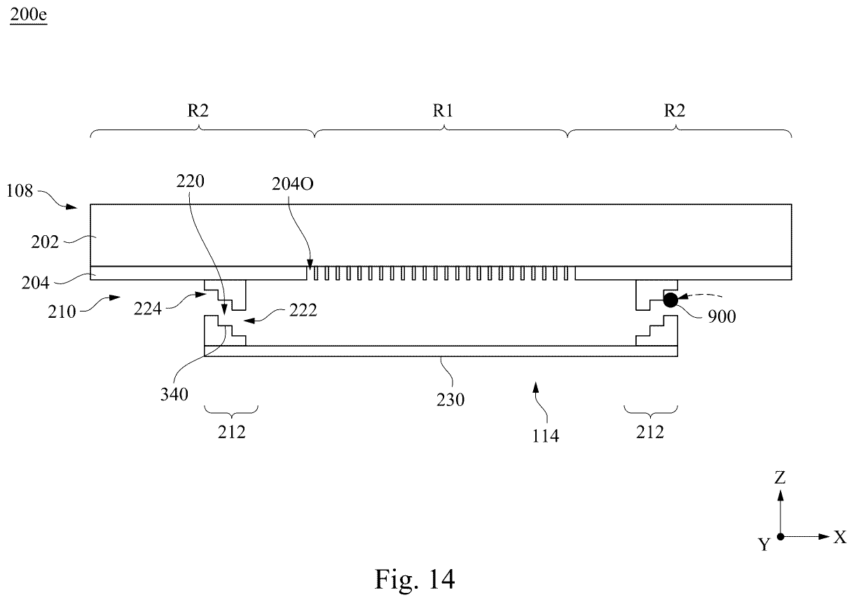

FIG. 14 is a cross-sectional view of an example pellicle-photomask structure 200e, in accordance with some embodiments of the present disclosure. The pellicle-photomask structure 200e is substantially the same as the pellicle-photomask structure 200 discussed previously, except that the vent hole 220 of the pellicle-photomask structure 200e includes a stepped inner surface structure 340 connecting the inner port 222 and the outer port 224, and the inner port 222 is at an elevation lower than the outer port 224.

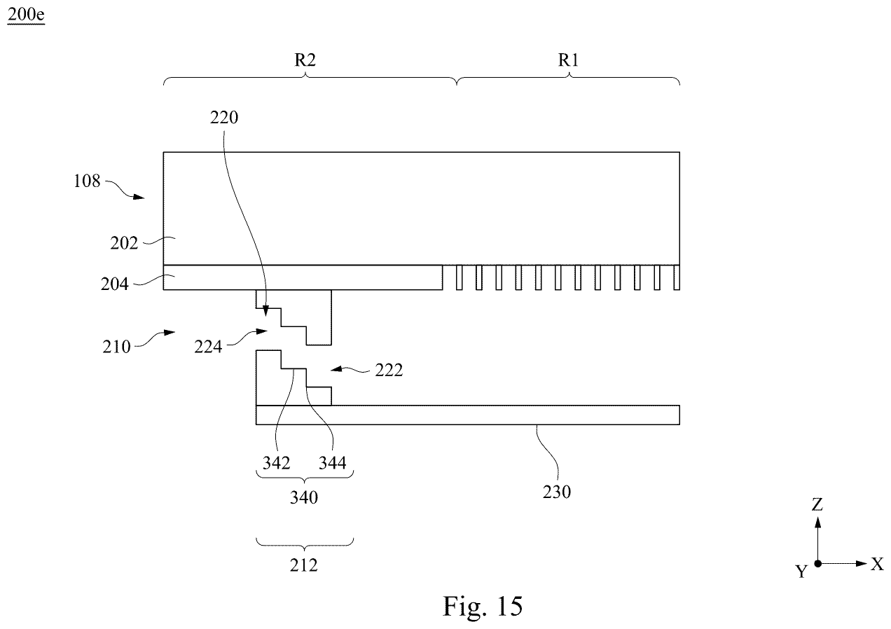

In some embodiments, as illustrated in the zoomed-in view of FIG. 15, the stepped inner surface structure 340 includes a series of alternating horizontal surfaces 342 and non-horizontal surfaces 344, creating a staircase-like profile. The horizontal surfaces 342 are oriented to extend along the X-direction, providing horizontal sections that contribute to the stepped configuration. These horizontal surfaces 342 are parallel to the bottom surface of the mask pattern 204. Interspersed between the horizontal surfaces 342 are the non-horizontal surfaces 344, which may be oriented to extend in the Z-direction, non-parallel with the bottom surface of the mask pattern 204. These non-horizontal surfaces 344 are substantially vertical, forming the risers of the stepped surface structure 310. The alternating arrangement of horizontal and non-horizontal surfaces 342, 344 creates a series of steps that facilitate the transition between different levels within the vent hole 220. The stepped configuration can potentially block the particles (e.g., particle 900 as shown in FIG. 14) from passing through the vent hole 220. Stated another way, the particles may be stuck in the vent hole 220, instead of passing through the vent hole 220, thereby preventing particles or contaminants from falling on the patterned region R1 of the photomask 108.

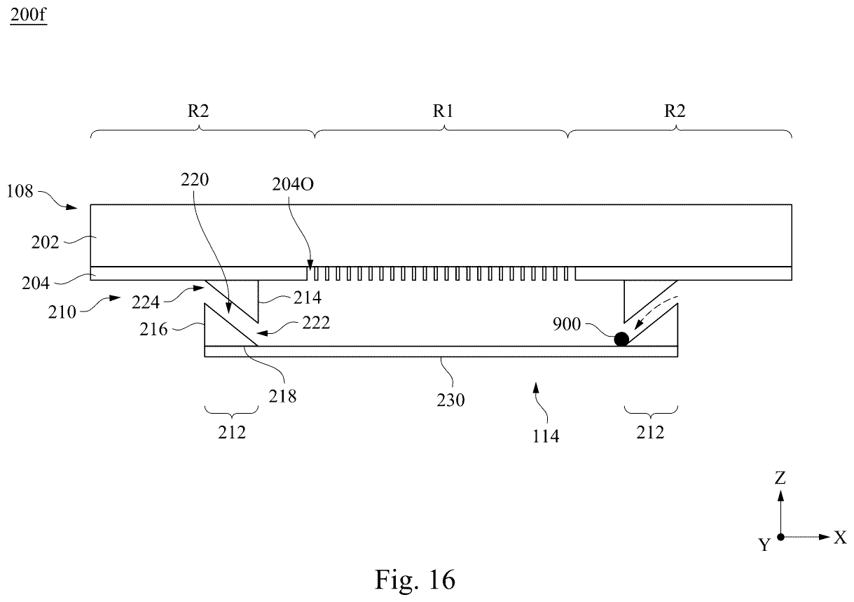

FIG. 16 is a cross-sectional view of an example pellicle-photomask structure 200f, in accordance with some embodiments of the present disclosure. The pellicle-photomask structure 200f is substantially the same as the pellicle-photomask structure 200 discussed previously, except that the vent hole 220 of the pellicle-photomask structure 200f includes an inner port 222 located at a lower elevation than an outer port 224. The elevation difference allows for guiding particles (e.g., particle 900) onto the pellicle membrane 230. Because the pellicle membrane 230 falls out of the focal plane of EUV radiation, the particles settle on the pellicle membrane 230 do not interfere with the lithographic process, thereby preventing defects in the printed pattern on the wafer 116.

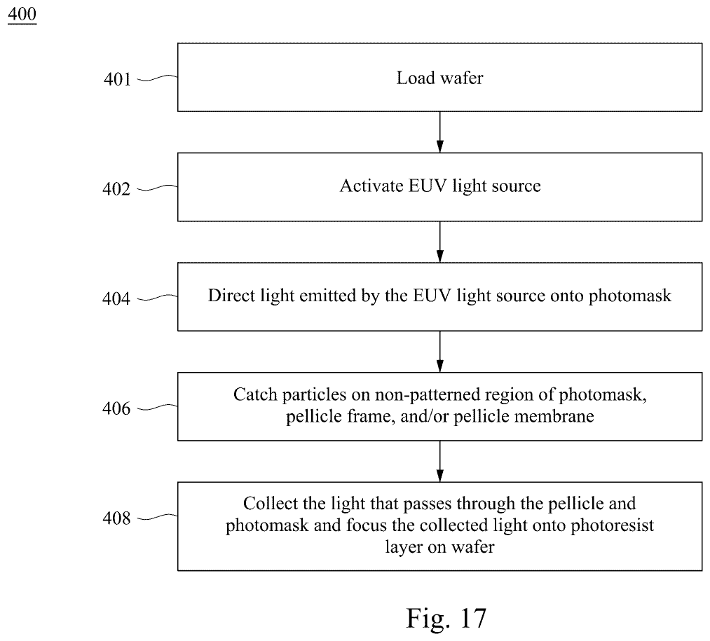

FIG. 17 illustrates a flowchart of a method 400 of fabricating a semiconductor device according to at least one embodiment of the present disclosure. At least some steps of the method 400 may be performed via a controller of an EUV lithography system, such as the lithography system illustrated in FIG. 1.

While the method 400 is illustrated and described below as a series of acts or events, it will be appreciated that the illustrated ordering of such acts or events are not to be interpreted in a limiting sense. For example, some acts may occur in different orders and/or concurrently with other acts or events apparat from those illustrated and/or described herein. In addition, not all illustrated acts may be required to implement one or more aspects or embodiments of the description herein. Further, one or more of the acts depicted herein may be carried out in one or more separate acts and/or phases.

The method 400 begins step 401. In step 401, a substrate (e.g., wafer) is loaded or transferred onto a substrate stage (e.g., wafer stage) by using, for example, an end effector of an automated robot arm.

In step 402, an EUV light source may be activated to pattern a resist layer on a substrate (where the substrate may be a semiconductor wafer). For example, the EUV light source may be part of a lithography system such as the system illustrated in FIG. 1 and discussed above. Thus, the EUV light source may generate light in extreme ultraviolet wavelengths (potentially by vaporizing droplets of metal into a highly ionized plasma).

In step 404, the light emitted by the EUV light source may be directed onto a photomask. The photomask may have a pattern etched into its surface, where the pattern is to be printed onto the resist layer on the substrate.

In step 406, foreign particles may be caught on a non-patterned region of the photomask (e.g., region R2 as discussed previously), on stepped inner surface structures (e.g., structures 310, 320, 330 or 340 as discussed previously) of vent holes of the pellicle frame, and/or on the pellicle membrane 230 as illustrated in FIG. 16, in order to keep the patterned region of photomask clear of the particles while the light is being directed onto the photomask.

In step 408, the light that passes through the pellicle and photomask may be collected by a projection optics module and focused onto the photoresist layer, to pattern the photoresist layer. For instance, exposure of the photoresist layer to the light may cause features having a target pitch to be printed in the photoresist. In some embodiments, the steps 402-408 may be continuously repeated during operation of the EUV light source (e.g., for multiple layers of the substrate).

It should be noted that the method 400 may be expanded to include additional steps or may be modified to include additional operations with respect to the steps outlined above. Furthermore, steps, blocks, functions or operations of the above described method 400 can be combined, separated, and/or performed in a different order from that described above, without departing from the examples of the present disclosure.

Based on the above discussions, it can be seen that the present disclosure in various embodiments offers advantages. It is understood, however, that other embodiments may offer additional advantages, and not all advantages are necessarily disclosed herein, and that no particular advantage is required for all embodiments. One advantage is that the likelihood of particles and/or contaminants falling on the patterned regions of the photomask can be reduced by using the improved vent hole design. Another advantage is that the occurrence of defects in the EUV printed patterns can be reduced, improving the yield and reliability of the EUV lithography system.

In some embodiments, a method includes loading a substrate onto a substrate stage; activating an extreme ultraviolet (EUV) light source to pattern a photoresist layer on the substrate; directing light emitted by the EUV light source onto a photomask covered with a pellicle. The pellicle includes a pellicle membrane vertically overlapping with a patterned region of the photomask, and pellicle frame disposed between the pellicle membrane and a non-patterned region of the photomask. The pellicle frame includes a frame bar and a vent hole extending through an inner surface and an outer surface of the frame bar, wherein at least a portion of an inner surface of the vent hole extends in a direction non-parallel with a bottom surface of the photomask. In some embodiments, the inner surface of the vent hole is a sloped surface. In some embodiments, a longitudinal axis of the vent hole extends into the non-patterned region of the photomask. In some embodiments, the vent hole has an inner port on the inner surface of the frame bar and an outer port on the outer surface of the frame bar, wherein the inner port of the vent hole is at an elevation different from an elevation of the outer port of the vent hole. In some embodiments, the inner port of the vent hole is at the elevation higher than the elevation of the outer port of the vent hole. In some embodiments, the inner port of the vent hole is at the elevation lower than the outer port of the vent hole. In some embodiments, the inner surface of the vent hole has a stepped structure in a cross-sectional view. In some embodiments, in the cross-sectional view, the stepped structure connects an inner port and an outer port of the vent hole, and the inner port is at a higher elevation than the outer port. In some embodiments, in the cross-sectional view, the stepped structure connects an inner port and an outer port of the vent hole, and the inner port is at a lower elevation than the outer port. In some embodiments, the photomask comprises a plurality of particle trapping recesses in the non-patterned region. In some embodiments, the photomask further comprises adhesive coatings in the plurality of particle trapping recesses.

In some embodiments, a method includes transferring a wafer coated with a photoresist layer onto a wafer stage, and performing a lithographic exposure process to the photoresist layer by using an extreme ultraviolet (EUV) tool. The EUV tool includes an EUV illumination source, a pellicle and a photomask on a downstream optical path, and a plurality of optics on a reflective path from the photomask. The pellicle covers a patterned region of the photomask, the pellicle comprises a pellicle frame disposed on a non-patterned region of the photomask, the pellicle frame has a vent hole having a first port on an inner surface of the pellicle frame and a second port on an outer surface of the pellicle frame, wherein the first port of the vent hole is at an elevation different from an elevation of the second port of the vent hole. In some embodiments, the first port of the vent hole is at the elevation higher than the elevation of the second port of the vent hole. In some embodiments, the first port of the vent hole is at the elevation lower than the elevation of the second port of the vent hole. In some embodiments, the vent hole has an inner surface extending from the first port to the second port along a non-horizontal direction. In some embodiments, the vent hole has a stepped inner surface extending from the first port to the second port. In some embodiments, the photomask comprises a plurality of particle trapping recesses in the non-patterned region.

In some embodiments, an apparatus includes an extreme ultraviolet (EUV) light source, a first plurality of optics positioned on a downstream optical path of the EUV light source, a pellicle and a photomask positioned on a downstream optical path of the first plurality of optics, a second plurality of optics positioned on a reflective path from the photomask, and a wafer stage positioned on a downstream optical path of the second plurality of optics. The pellicle overlaps with a patterned region of the photomask, the pellicle comprises a pellicle membrane and a pellicle frame disposed between the pellicle membrane and a non-patterned region of the photomask, the pellicle frame has a vent hole that allows for a flow of air passing through the pellicle frame, and at least a portion of an inner surface of the vent hole extends in a direction non-parallel with a bottom surface of the photomask. In some embodiments, the vent hole has an inner port on an inner surface of the pellicle frame and an outer port on an outer surface of the pellicle frame. The inner port is at an elevation higher than an elevation of the outer port. In some embodiments, the inner port is at an elevation lower than an elevation of the outer port. In some embodiments, the photomask has a plurality of particle trapping recesses in the non-patterned region of the photomask.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
loading a substrate onto a substrate stage;
activating an extreme ultraviolet (EUV) light source to pattern a photoresist layer on the substrate;
directing light emitted by the EUV light source onto a photomask covered with a pellicle, wherein the pellicle comprises:
a pellicle membrane vertically overlapping with a patterned region of the photomask; and
a pellicle frame disposed between the pellicle membrane and a non-patterned region of the photomask, wherein the pellicle frame comprises a frame bar and a vent hole extending through an inner surface and an outer surface of the frame bar, wherein at least a portion of an inner surface of the vent hole extends in a direction non-parallel with a bottom surface of the photomask.

2. The method of claim 1, wherein the inner surface of the vent hole is a sloped surface.

3. The method of claim 1, wherein a longitudinal axis of the vent hole extends into the non-patterned region of the photomask.

4. The method of claim 1, wherein the vent hole has an inner port on the inner surface of the frame bar and an outer port on the outer surface of the frame bar, wherein the inner port of the vent hole is at an elevation different from an elevation of the outer port of the vent hole.

5. The method of claim 4, wherein the inner port of the vent hole is at the elevation higher than the elevation of the outer port of the vent hole.

6. The method of claim 4, wherein the inner port of the vent hole is at the elevation lower than the outer port of the vent hole.

7. The method of claim 1, wherein the inner surface of the vent hole has a stepped structure in a cross-sectional view.

8. The method of claim 7, wherein in the cross-sectional view, the stepped structure connects an inner port and an outer port of the vent hole, and the inner port is at a higher elevation than the outer port.

9. The method of claim 7, wherein in the cross-sectional view, the stepped structure connects an inner port and an outer port of the vent hole, and the inner port is at a lower elevation than the outer port.

10. The method of claim 1 wherein the photomask comprises a plurality of particle trapping recesses in the non-patterned region.

11. A method, comprising:
transferring a wafer coated with a photoresist layer onto a wafer stage; and
performing a lithographic exposure process to the photoresist layer by using an extreme ultraviolet (EUV) tool, the EUV tool comprising:
an EUV illumination source;
a pellicle and a photomask on a downstream optical path of the EUV illumination source, wherein the pellicle covers a patterned region of the photomask, the pellicle comprises a pellicle frame disposed on a non-patterned region of the photomask, the pellicle frame has a vent hole having a first port on an inner surface of the pellicle frame and a second port on an outer surface of the pellicle frame, wherein the first port of the vent hole is at an elevation different from an elevation of the second port of the vent hole; and
a plurality of optics on a reflective path from the photomask.

12. The method of claim 11, wherein the first port of the vent hole is at the elevation higher than the elevation of the second port of the vent hole.

13. The method of claim 11, wherein the first port of the vent hole is at the elevation lower than the elevation of the second port of the vent hole.

14. The method of claim 11, wherein the vent hole has an inner surface extending from the first port to the second port along a non-horizontal direction.

15. The method of claim 11, wherein the vent hole has a stepped inner surface extending from the first port to the second port.

16. The method of claim 11, wherein the photomask comprises a plurality of particle trapping recesses in the non-patterned region.

17. An apparatus, comprising:
an extreme ultraviolet (EUV) light source;
a first plurality of optics positioned on a downstream optical path of the EUV light source;
a pellicle and a photomask positioned on a downstream optical path of the first plurality of optics, wherein the pellicle overlaps with a patterned region of the photomask, the pellicle comprises a pellicle membrane and a pellicle frame disposed between the pellicle membrane and a non-patterned region of the photomask, the pellicle frame has a vent hole that allows for a flow of air passing through the pellicle frame, wherein at least a portion of an inner surface of the vent hole extends in a direction non-parallel with a bottom surface of the photomask;
a second plurality of optics positioned on a reflective path from the photomask; and
a wafer stage positioned on a downstream optical path of the second plurality of optics.

18. The apparatus of claim 17, wherein the vent hole has an inner port on an inner surface of the pellicle frame and an outer port on an outer surface of the pellicle frame, wherein the inner port is at an elevation higher than an elevation of the outer port.

19. The apparatus of claim 17, wherein the vent hole has an inner port on an inner surface of the pellicle frame and an outer port on an outer surface of the pellicle frame, wherein the inner port is at an elevation lower than an elevation of the outer port.

20. The apparatus of claim 17, wherein the photomask has a plurality of particle trapping recesses in the non-patterned region of the photomask.
